(19) United States
(12) Patent Application Publication
(10) Pub. No.: US 2025/0140643 A1
(43) Pub. Date: May 1, 2025

(54) PACKAGE STRUCTURE

(71) Applicant: Taiwan Semiconductor Manufacturing Company, Ltd., Hsinchu (TW)

(72) Inventors: Chao-Wei Li, Hsinchu City (TW); Chun-Yen Lan, Hsinchu County (TW); Yu-Wei Lin, New Taipei City (TW); Sheng-Hsiang Chiu, Tainan City (TW); Tzu-Ting Chou, Hsinchu City (TW); Pei-Hsuan Lee, Tainan City (TW); Chih-Wei Lin, Hsinchu County (TW); Ching-Hua Hsieh, Hsinchu (TW)

(73) Assignee: Taiwan Semiconductor Manufacturing Company, Ltd., Hsinchu (TW)

(21) Appl. No.: 18/499,230

(22) Filed: Nov. 1, 2023

(51) Int. Cl. H01L 23/42; H01L 23/00; H01L 23/31; H01L 23/498

(52) U.S. Cl. CPC H01L 23/42; H01L 23/3128; H01L 23/49816; H01L 24/16; H01L 2224/16225; H01L 2924/3511

(57) ABSTRACT

A package structure is provided. The package structure comprises a package substrate, an electronic device, a thermal interface material (TIM), a lid and an insulating encapsulant. The electronic device is disposed on and electrically connected to the package substrate. The TIM is disposed on the electronic device. The lid is disposed on the TIM. The insulating encapsulant is disposed on the package substrate and laterally encapsulates the electronic device and the TIM. A lateral dimension of the TIM is greater than a lateral dimension of the electronic device.

### BACKGROUND

As the need for electronic devices to process larger amount of data at high speed grows, significant challenges are posed in design and packaging of these devices. Liquid metal thermal interface material (TIM) is a kind of high dissipating thermal performance material that can be utilized on a lid type package to improve dissipating thermal performance. Therefore, the improved the TIM and the lid are desired as a development of a semiconductor process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a package structure in accordance with some embodiments.

FIG. 2 to FIG. 5 illustrate the cross-sectional views of a package structure in accordance with various embodiments in accordance with some embodiments.

FIG. 6 to FIG. 7 illustrate the cross-sectional views of intermediate stages in the formation of a package structure in accordance with some embodiments.

FIG. 8 to FIG. 9 illustrate the cross-sectional views of intermediate stages in the formation of a package structure in accordance with some embodiment.

FIG. 10 to FIG. 11 illustrate the cross-sectional views of intermediate stages in the formation of a package structure in accordance with some embodiment.

FIG. 12 to FIG. 17 illustrate the cross-sectional views of a package structure in accordance with various embodiments in accordance with some embodiments.

FIG. 18 to FIG. 23 illustrate the cross-sectional views of a package structure in accordance with various embodiments in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package structure is provided. The package structure comprises a package substrate, an electronic device, a thermal interface material (TIM), a lid and an insulating encapsulant. The electronic device is disposed on and electrically connected to the package substrate. The TIM is disposed on the electronic device. The lid is disposed on the TIM. The insulating encapsulant is disposed on the package substrate and laterally encapsulates the electronic device and the TIM. A lateral dimension of the TIM is greater than a lateral dimension of the electronic device. The package structure is proposed to prevent a liquid metal TIM leakage to overcome TIM coverage issue when package structure warpage changes. Therefore, a reliability and a dissipating thermal performance of the package structure are improved. In accordance with some embodiments of the present disclosure, Embodiments discussed herein are to provide examples to enable making or using the subject matter of this disclosure, and a person having ordinary skill in the art will readily understand modifications that can be made while remaining within contemplated scopes of different embodiments.

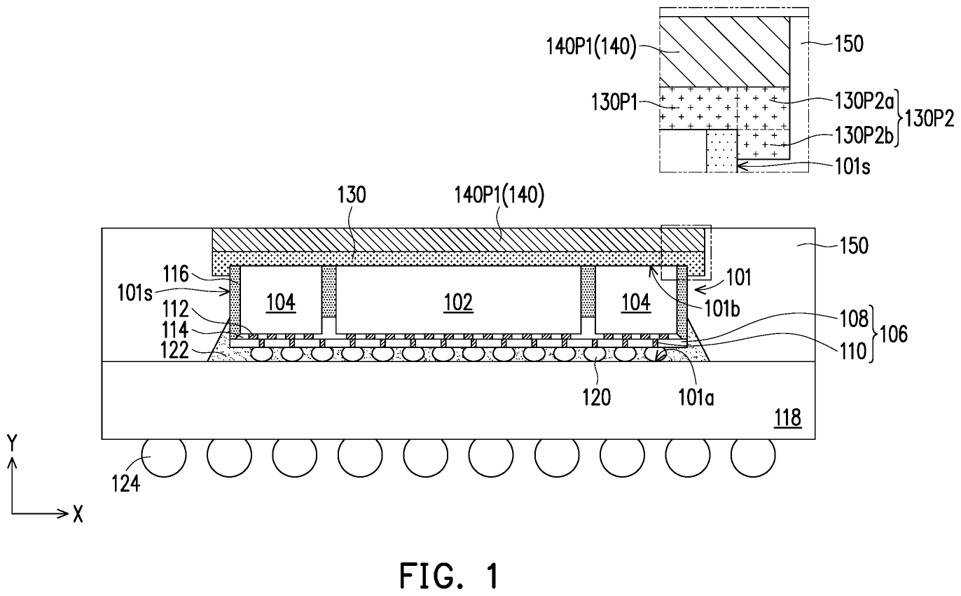

FIG. 1 is a cross-sectional view of a package structure in accordance with some embodiments.

Referring to FIG. 1, the package structure may include multiple semiconductor dies. For instance, the package structure may include semiconductor dies such as a device die 102 and die stacks 104 aside the device die 102. The device die 102 may be a system-on-chip (SOC) device die, and each of the die stacks 104 may include a stack of memory dies (not shown). The device die 102 and the die stacks 104 may be arranged side by side, and are laterally separated with one another. In some embodiments, the device die 102 and the die stacks 104 are attached to an interposer substrate 106. The interposer substrate 106 may include a semiconductor substrate 108 (e.g., a silicon substrate) and through substrate vias (TSV) 110 penetrating through the semiconductor substrate 108. The TSVs 110 are electrically connected to the device die 102 and the die stacks 104, and establish conduction paths extending between opposite sides of the semiconductor substrate 108. Although not shown, the interposer substrate 106 may further include metallization layers at one or both sides of the semiconductor substrate 108, and the TSVs 110 may be connected to one or both sides of the interposer substrate 106 through interconnection elements (e.g., a combination of conductive lines and conductive vias) in the metallization layers.

In alternative embodiments, the interposer substrate 106 may include a stack of polymer layers and interconnection elements spreading in the stack of polymer layers. In other embodiments, the interposer substrate 106 may include a molding compound substrate with vias penetrating through, and may further include metallization layers at one or both sides of the molding compound substrate. Interconnection elements (e.g., a combination of conductive lines and conductive vias) in the metallization layers may be electronically connected to the vias extending through the molding compound substrate.

The device die 102 and the die stacks 104 may be attached to the interposer substrate 106 via electrical connectors 112. As an example, the electrical connectors 112 may be micro-bumps. In some embodiments, the electrical connectors 112 are laterally surrounded by an underfill 114 spreading in a space between the interposer substrate 106 and the attached device die 102 and die stacks 104. Further, in some embodiments, the device die 102 and the die stacks 104 are laterally encapsulated by an gap filling layer 116. Sidewalls of the interposer substrate 106 substantially align with sidewalls of the gap filling layer 116. A surface of the gap filling layer 116 may be coplanar with surfaces of the device die 102 and the die stacks 104 that are facing away from the interposer substrate 106.

Further, in some embodiments, the interposer substrate 106 attached with the device die 102 and the die stacks 104 may be further attached to a package substrate 118, along with other electronic components (not shown, such as passive devices). In some embodiments, although not shown, the package substrate 118 includes a dielectric core layer and build-up layers at one or both sides of the dielectric core layer, and conductive wirings may spread in the build-up layers. In alternative embodiments, the package substrate 118 is a core-less substrate, and includes a stack of build-up layers and conductive wirings spreading in the stack of build-up layers. Signals from the device die 102 and the die stacks 104 can be routed to another side of the package substrate 118 through the conductive wirings in the package substrate 118. In some embodiments, the interposer substrate 106 is attached to the package substrate 118 through electrical connectors 120 to form an electronic device 101. As an example, the electrical connectors 120 may be controlled collapsed chip connection (C4) bumps.

The electronic device 101 comprises the device die 102, the die stacks 104, the interposer substrate 106, the electrical connectors 112, the underfill 114, the gap filling layer 116, and the electrical connectors 120. The electronic device 101 has a first side 101a and a second side 101b. The second side 101b is opposite to the first side 101a. The package substrate 118 is disposed on the first side 101a of the electronic device 101. The TIM 130 is disposed on the second side 101b of the electronic device 101. The electronic device 101 has sidewalls 101s extending between the first side 101a and the second side 101b. The sidewalls 101s of the electronic device 101 comprise sidewalls of the gap filling layer 116.

In some embodiments, electrical connectors 120 are laterally surrounded by an underfill 122 spreading a space between the interposer substrate 106 and the package substrate 118. In some embodiments, the underfill 122 encapsulates the sidewalls 101s of the electronic device 101. The electronic device 101 is disposed on and electrically connected to the package substrate 118 through electrical connectors 120. Moreover, in some embodiments, electrical connectors 124 are disposed at a side of the package substrate 118 facing away from the interposer substrate 106, and may be functioned as inputs/outputs (I/Os) of the package structure. As an example, the electrical connectors 124 may be ball grid array (BGA) balls.

In some embodiments, a thermal interface material (TIM) 130 is applied on the second side 101b of the electronic device 101. In some embodiments, the TIM 130 may be a gel-type TIM formed on the electronic device 101. The TIM 130 may be a pre-fabricated film and is placed on the electronic device 101 through a pasting process. In some embodiments, the TIM 130 may be provided by a dispense process or a printing process. The material of the TIM 130 may be or include metallic thermal interface material. In some embodiments, the TIM 130 is formed by purely metallic materials. For example, the TIM 130 is free of organic material and polymeric material. In some embodiments, the TIM 130 includes solder, tin, bismuth, lead, cadmium, zinc, gallium, indium, tellurium, mercury, thallium, antimony, selenium, polonium, or a combination thereof. In some embodiments, a thermal conductivity (k) of the TIM 130 ranges from about 10 W/(m·K) to about 90 W/(m·K). On the other hand, a Young's modulus of the TIM 130 ranges from about 5 GPa to about 70 GPa.

In some embodiments, a lateral dimension of the TIM 130 may be greater than a lateral dimension of the electronic device 101. In some embodiments, the sidewalls of the gap filling layer 116 may be partially covered by the TIM 130.

In some embodiments, a lid 140 is disposed on the TIM 130. The lid 140 comprises a horizontal portion 140P1 extending along the TIM 130. In some embodiments, a lateral dimension of the TIM 130 substantially equals to a lateral dimension of the lid 140. In alternative embodiments, a lateral dimension of the lid 140 is greater than a lateral dimension of the TIM 130.

In some embodiments, an insulating encapsulant 150 is disposed on the package substrate 118 and laterally encapsulates the electronic device 101, the TIM 130 and the lid 140. In some embodiments, sidewalls of the TIM 130 are covered by the insulating encapsulant 150.

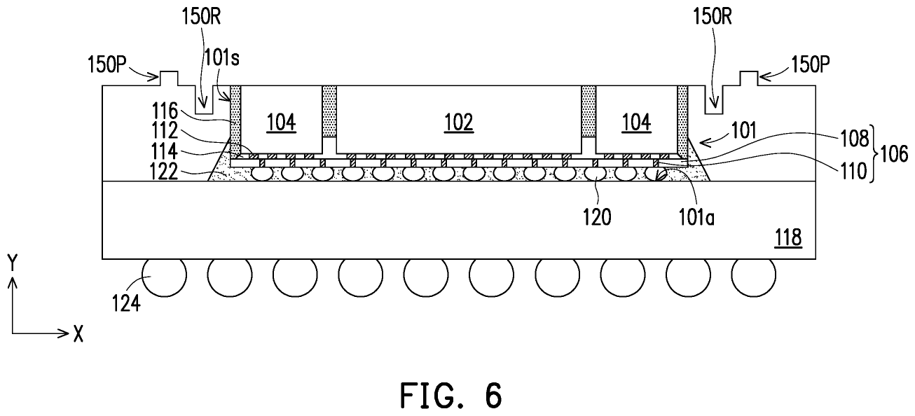

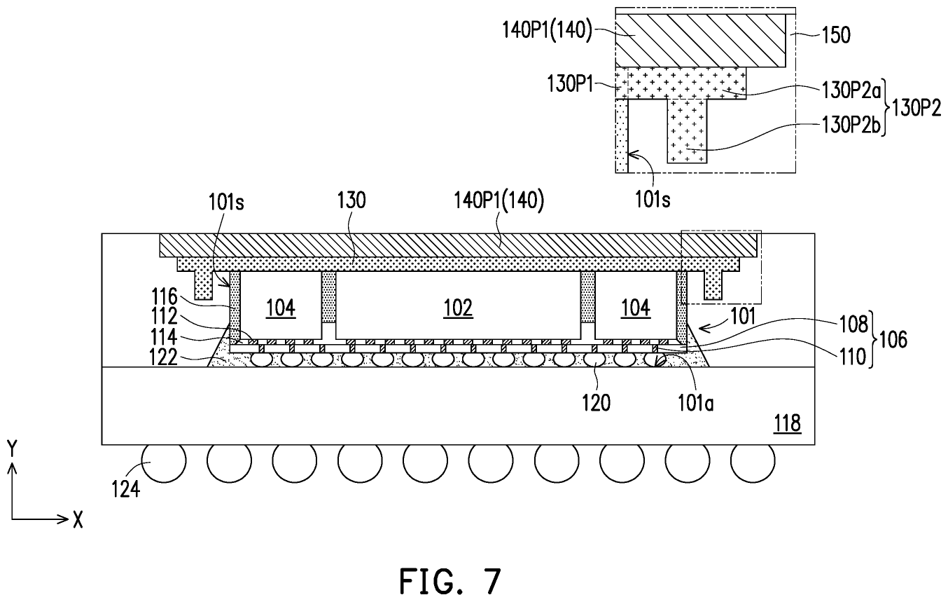

In some embodiments, referring to FIG. 6 to FIG. 7, a first portion of the insulating encapsulant 150 is formed, then the TIM 130 fills in a space within the first portion of the insulating encapsulant 150. After forming the TIM 130, a second portion of the insulating encapsulant 150 is formed on the first portion of the insulating encapsulant 150.

In some embodiments, a material the insulating encapsulant 150 may be a molding compound, a molding underfill (MUF), a resin (such as epoxy), or the like. In some embodiments, the insulating encapsulant 150 is formed by a molding process. For example, the insulating encapsulant 150 may be formed by a compression molding process, an injection molding process, or the like. Thereafter, a portion of the insulating encapsulant 150, a portion of are removed through a grinding process until the lid is revealed. A surface of the lid 140 may be coplanar with a surface of the insulating encapsulant 150. The grinding process includes, for example, a mechanical grinding process, a chemical mechanical polishing (CMP), or the like. In some embodiments, an underfill 122 may be replaced with the MUF, and the MUF spread a space between the interposer substrate 106 and the package substrate 118 and laterally encapsulates the electronic device 101, the TIM 130 and the lid 140.

In some embodiments, the TIM 130 comprises a main portion 130P1 sandwiched between the lid 140 and the electronic device 101, and a protruding portion 130P2 extending from the main portion 130P1 into the insulating encapsulant 150. A dashed line (shown in FIG. 1) aligned with the sidewalls 101s of the electronic device 101 is a boundary line between the main portion 130P1 and the protruding portion 130P2. In some embodiments, the main portion 130P1 may be in contact with the lid 140 and the electronic device 101. In some embodiments, the protruding portion 130P2 is a ring portion surrounding and aligned with an edge of the electronic device 101, viewing from a top view (not shown herein). In some embodiments, the protruding portion 130P2 of the TIM 130 may be in contact with the lid 140, the insulating encapsulant 150 and the sidewalls 101s of the electronic device 101. In some embodiments, the protruding portion 130P2 of the TIM 130 may be at least partially surrounded by the insulating encapsulant 150.

In some embodiments, a volume ratio of the protruding portion 130P2 of the TIM 130 and the main portion 130P1 of TIM 130 is about 0.2 to 2.0. In some embodiments, a thickness of the main portion 130P1 of the TIM 130 sandwiched between the lid 140 and the electronic device 101 is about 20 μm to 150 μm. In some embodiments, the protruding portion 130P2 of the TIM 130 comprises a plate 130P2a extending along and in contact with the horizontal portion 140P1 of the lid 140, and comprises a protrusion 130P2b extending from the plate 130P2a to the package substrate 118 and extending into the insulating encapsulant 150. A dashed line (shown in FIG. 1) aligned with the second side 101b of the electronic device 101 is a boundary line between the plate 130P2a and the protrusion 130P2b. In some embodiments, the protrusion 130P2b of the TIM 130 may cover the sidewalls 101s of the electronic device 101. The protrusion 130P2b of the TIM 130 is disposed between the electronic device 101 and the insulating encapsulant 150.

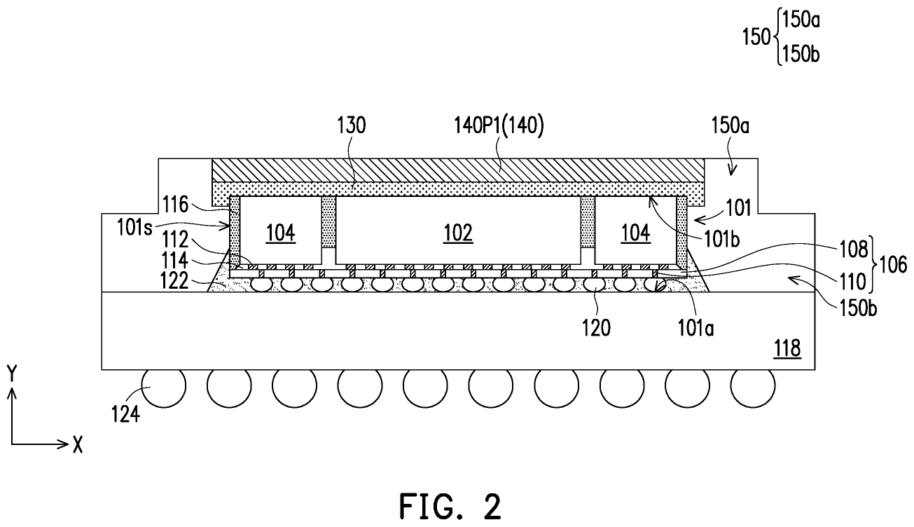

FIG. 2 to FIG. 5 illustrate the cross-sectional views of a package structure in accordance with various embodiments in accordance with some embodiments.

Referring to FIG. 2, except for a shape the insulating encapsulant 150, the definition of the reference symbols and labeled representations are the same as FIG. 1, and will not be repeated herein.

In some embodiments, the insulating encapsulant 150 comprises an upper portion 150a, and a lower portion 150b extending between the package substrate 118 and the upper portion 150a. In some embodiments, a lateral dimension of the upper portion 150a of the insulating encapsulant 150 is less than a lateral dimension of the lower portion 150b of the insulating encapsulant 150. In some embodiments, a lateral dimension of the upper portion 150a of the insulating encapsulant 150 is greater than lateral dimensions of the TIM 130, the lid 140 and the electronic device 101. In the embodiment, the insulating encapsulant 150 may not only protect the electronic device 101, but also minimize warpage and stress of the package structure.

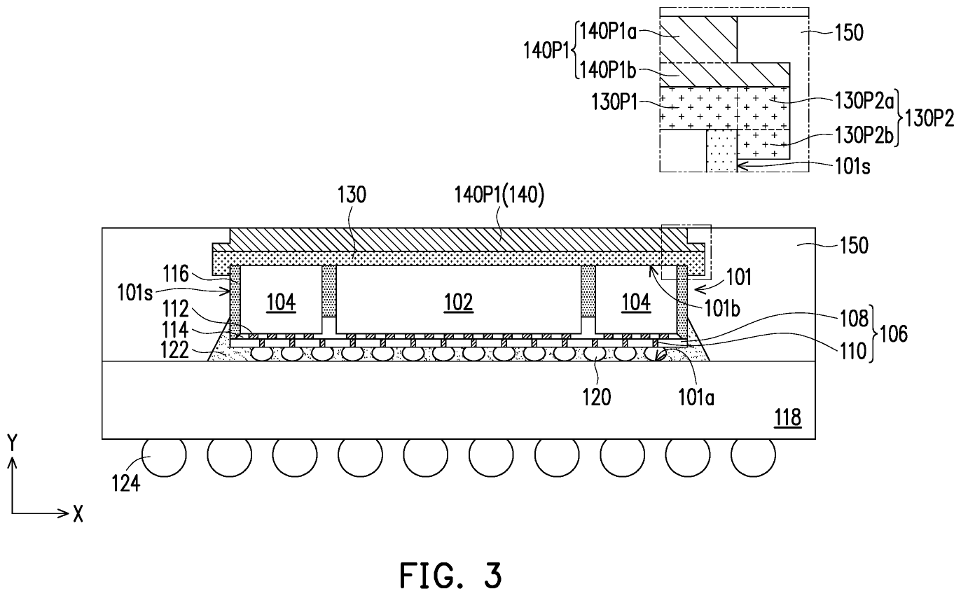

Referring to FIG. 3, except for a shape the horizontal portion 140P1 of the lid 140, the definition of the reference symbols and labeled representations are the same as FIG. 1, and will not be repeated herein.

In some embodiments, the horizontal portion 140P1 of the lid 140 comprises an upper portion 140P1a revealed from the insulating encapsulant 150, and a lower portion 140P1b extending between the TIM 130 and the upper portion 140P1a. A dashed line (shown in FIG. 3) is a boundary line between the upper portion 140P1a and the lower portion 140P1b. In some embodiments, a lateral dimension of the upper portion 140P1a of the lid 140 is less than a lateral dimension of the lower portion 140P1b of the lid 140. In some embodiments, a lateral dimension of the upper portion 140P1a of the lid 140 is less than a lateral dimension of the TIM 130. In some embodiments, a lateral dimension of the TIM 130 substantially equals to a lateral dimension of the lower portion 140P1b of the lid 140. In some embodiments, the insulating encapsulant 150 extends to sidewalls the upper portion 140P1a of the lid 140 and a top surface of the lower portion 140P1b of the lid 140. In alternative embodiments, a lateral dimension of the lower portion 140P1b of the lid 140 is greater than a lateral dimension of the TIM 130. In the embodiment, the insulating encapsulant 150 laterally encapsulates the lid 140 with a larger contact area to improve an adhesion between the lid 140 and the insulating encapsulant 150.

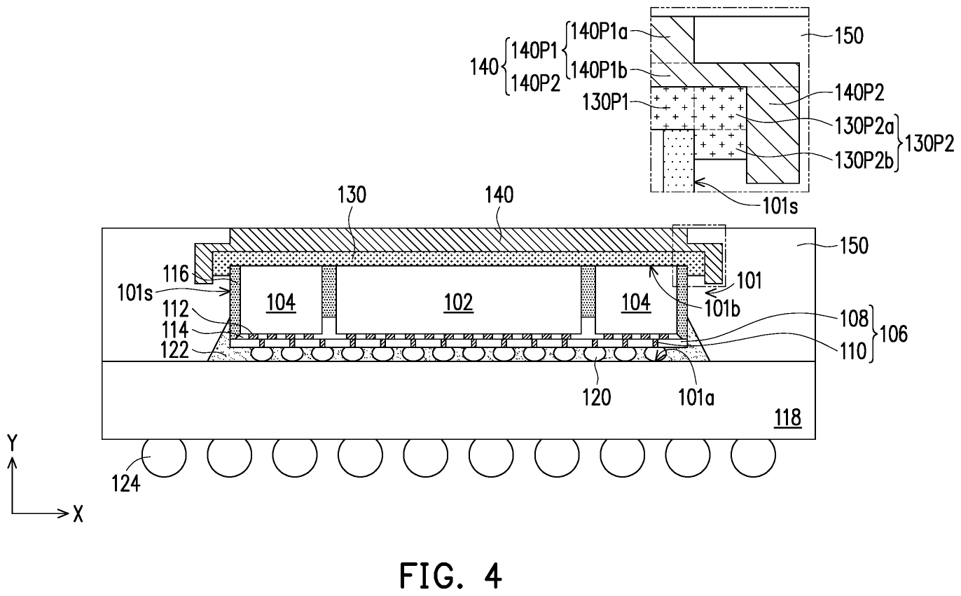

Referring to FIG. 4, except for a shape the lid 140, the definition of the reference symbols and labeled representations are the same as FIG. 3, and will not be repeated herein.

In some embodiments, the lid 140 comprises a horizontal portion 140P1 and a vertical portion 140P2. In some embodiments, the horizontal portion 140P1 extends along the TIM 130 in a direction X. In some embodiments, the horizontal portion 140P1 comprises the upper portion 140P1a and the lower portion 140P1b. In some embodiments, the lid 140 comprises the vertical portion 140P2 extending from the lower portion 140P1b of the horizontal portion 140P1 to the package substrate 118 in direction Y. The direction Y is vertical to the direction X. A dashed line (shown in FIG. 4) is a boundary line between the horizontal portion 140P1 and the vertical portion 140P2. In some embodiments, the vertical portion 140P2 of the lid 140 is a ring shape wrapping around the protruding portion 130P2 of the TIM 130, viewing from a top view. In some embodiments, the vertical portion 140P2 may be a fastening ring structure laterally surrounding the electronic device 101 from a top view.

In some embodiments, the vertical portion 140P2 of the lid 140 extends along a sidewall of the protruding portion 130P2 of the TIM 130. In some embodiments, the vertical portion 140P2 of the lid 140 extends along a sidewall of the protrusion 130P2b of the protruding portion 130P2 of the TIM 130. In some embodiments, sidewalls of the TIM 130 are covered by the lid 140. In some embodiments, the protrusion 130P2b of the TIM 130 is sandwiched between the electronic device 101 and the vertical portion 140P2 of the lid 140. In the embodiment, the insulating encapsulant 150 laterally encapsulates the lid 140 with a larger contact area to improve the adhesion between the lid 140 and the insulating encapsulant 150. Meanwhile, the protruding portion 130P2 of the TIM 130 sandwiched between the electronic device 101 and the vertical portion 140P2 of the lid 140 may also minimize the lateral leakage of the liquid metal TIM 130.

In some embodiments, the lower portion 140P1b of the lid 140 is in contact with the main portion 130P1 and the plate 130P2a of the TIM 130. In some embodiments, the vertical portion 140P2 of the lid 140 is in contact with the plate 130P2a and the protrusion 130P2b of the TIM 130. In some embodiments, a vertical dimension of the vertical portion 140P2 of the lid 140 is greater than a vertical dimension of the protruding portion 130P2 of the TIM 130. In alternative embodiments, a vertical dimension of the vertical portion 140P2 of the lid 140 substantially equals to a vertical dimension of the protruding portion 130P2 of the TIM 130.

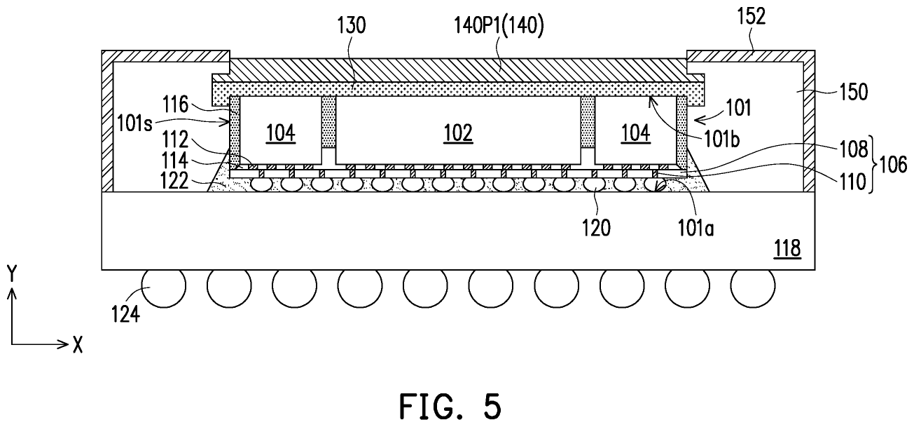

Referring to FIG. 5, except for an additional EMI (electromagnetic interference) shielding layer 152 and the insulating encapsulant 150 partially encapsulating the lid 140, the definition of the reference symbols and labeled representations are the same as FIG. 3, and will not be repeated herein.

In some embodiments, the EMI shielding layer 152 is disposed on the insulating encapsulant 150 and covers the insulating encapsulant 150. In some embodiment, the EMI shielding layer 152 may be formed by any suitable material and any suitable process. In some embodiment, the EMI shielding layer 152 may be a block-shaped metal plate or other suitable conductive block-shaped layer. In some embodiments, the EMI shielding layer 152 is in contact with the lid 140. In some embodiments, the EMI shielding layer 152 is in contact with sidewalls of the lid 140. In some embodiments, the EMI shielding layer 152 is in contact with sidewalls of the upper portion 140P1a of the lid 140. In other embodiments, the insulating encapsulant 150 may also applied in the package structure shown in FIG. 1, FIG. 2 and FIG. 4. In some embodiments, the EMI shielding layer 152 may reduce the unexpected electrical interference resulted from the electromagnetic wave signal.

FIG. 6 to FIG. 7 illustrate the cross-sectional views of intermediate stages in the formation of a package structure in accordance with some embodiments.

Referring to FIG. 6 to FIG. 7, unless further description as follows, the definition of the reference symbols and labeled representations are the same as FIG. 1, and will not be repeated herein.

Referring to FIG. 6, before forming the TIM 130 and the lid 140, a first portion of the insulating encapsulant 150 is formed on the package substrate 118 and laterally encapsulates the electronic device 101. In some embodiments, the first portion of the insulating encapsulant 150 comprises microstructures such as stoppers 150P and trenches 150R on a side facing away from the package substrate 118.

In some embodiments, the stoppers 150P protrude from on a surface of the insulating encapsulant 150 aligned with the second side 101b of the electronic device 101. In some embodiments, the trenches 150R extends from the surface, which the insulating encapsulant 150 is aligned with the second side 101b of the electronic device 101, to the package substrate 118. In some embodiments, the trenches 150R of the insulating encapsulant 150 are between the stoppers 150P of the insulating encapsulant 150. In some embodiments, the stoppers 150P and the trenches 150R of the insulating encapsulant 150 may be formed with any suitable number and configuration on the surface of the insulating encapsulant 150 aligned with the second side 101b of the electronic device 101. The numbers and the configuration of the stoppers 150P and the trenches 150R of the insulating encapsulant 150 are not limited thereto and are not limited by the figures.

Referring to FIG. 7, after forming the first portion of the insulating encapsulant 150, the TIM 130, the lid 140 and a second portion of the insulating encapsulant 150 are formed on the first portion of the insulating encapsulant 150. In some embodiments, the TIM 130, the lid 140, and the second portion of the insulating encapsulant 150 are formed in an order. In some embodiments, the lid 140 is provided and disposed on the TIM 130. In some embodiments, a lateral dimension of the lid 140 is greater than a lateral dimension of the TIM 130. In some embodiments, the TIM 130 fills in a space between the stoppers 150P of the insulating encapsulant 150, and fills into the trenches 150R of the insulating encapsulant 150, to form a protruding portion 130P2 of the TIM 130 with a T-shape. In some embodiments, the gel-type TIM 130 may be laterally stopped by the stoppers 150P.

In some embodiments, the protrusion 130P2b of protruding portion 130P2 of the TIM 130 extends from the plate 130P2a to the package substrate 118 and extends into the insulating encapsulant 150. In some embodiments, the protrusion 130P2b of protruding portion 130P2 of the TIM 130 is separated from sidewalls of the electronic device 101 by the insulating encapsulant 150. In some embodiments, the protrusion 130P2b of protruding portion 130P2 of the TIM 130 may be formed with any suitable number and configuration. The numbers and the configuration of the protrusion 130P2b of protruding portion 130P2 of the TIM 130 are not limited thereto and are not limited by the figures.

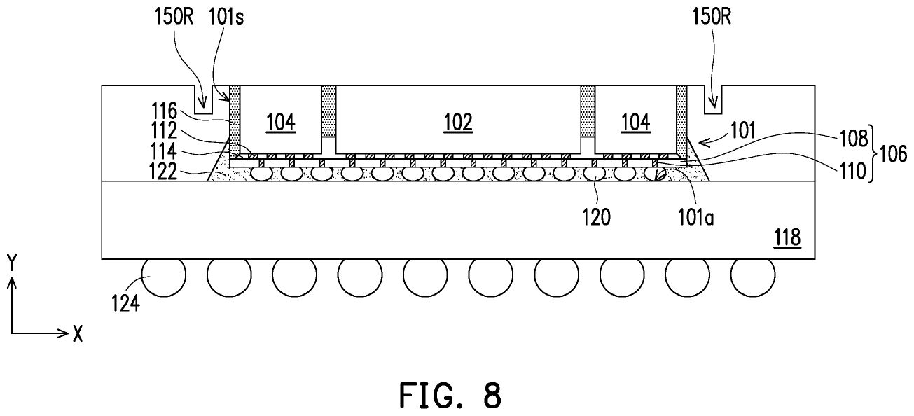

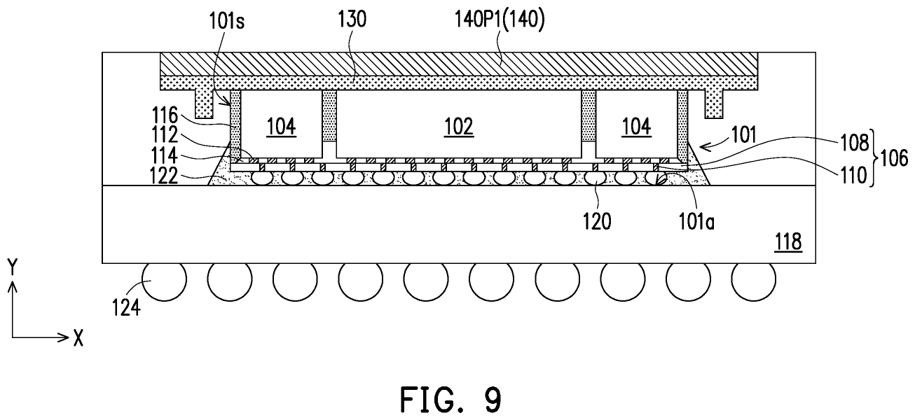

FIG. 8 to FIG. 9 illustrate the cross-sectional views of intermediate stages in the formation of a package structure in accordance with some embodiment.

Referring to FIG. 8 to FIG. 9, except for omitting the stoppers 150P of FIG. 6, the definition of the reference symbols and labeled representations are the same as FIG. 6 to FIG. 7, and will not be repeated herein.

Referring to FIG. 8, before forming the TIM 130 and the lid 140, a first portion of the insulating encapsulant 150 with the trenches 150R is formed on the package substrate 118 and laterally encapsulates the electronic device 101. Referring to FIG. 9, in some embodiments, a lateral dimension of the lid 140 substantially equals to a lateral dimension of the TIM 130. In alternative embodiments, a lateral dimension of the lid 140 is greater than a lateral dimension of the TIM 130.

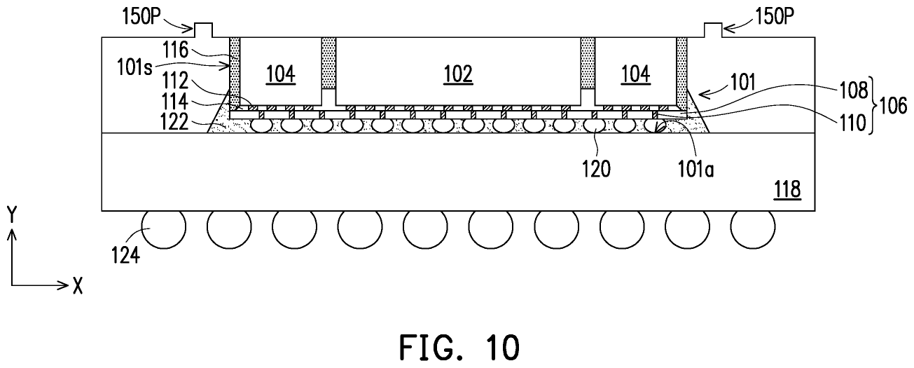

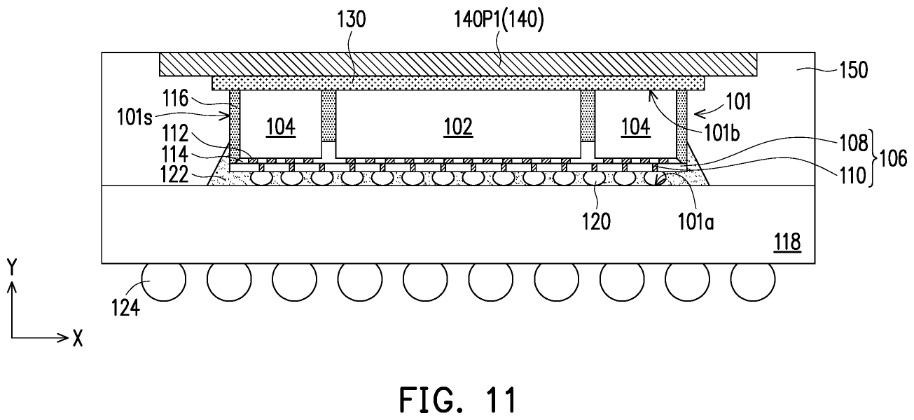

FIG. 10 to FIG. 11 illustrate the cross-sectional views of intermediate stages in the formation of a package structure in accordance with some embodiment.

Referring to FIG. 10 to FIG. 11, except for omitting the trenches 150R of FIG. 6, the definition of the reference symbols and labeled representations are the same as FIG. 6 to FIG. 7, and will not be repeated herein.

Referring to FIG. 10, before forming the TIM 130 and the lid 140, a first portion of the insulating encapsulant 150 with the stoppers 150P is formed on the package substrate 118 and laterally encapsulates the electronic device 101. Referring to FIG. 11, in some embodiments, a lateral dimension of the lid 140 is greater than a lateral dimension of the TIM 130. In alternative embodiments, a lateral dimension of the lid 140 substantially equals to a lateral dimension of the TIM 130.

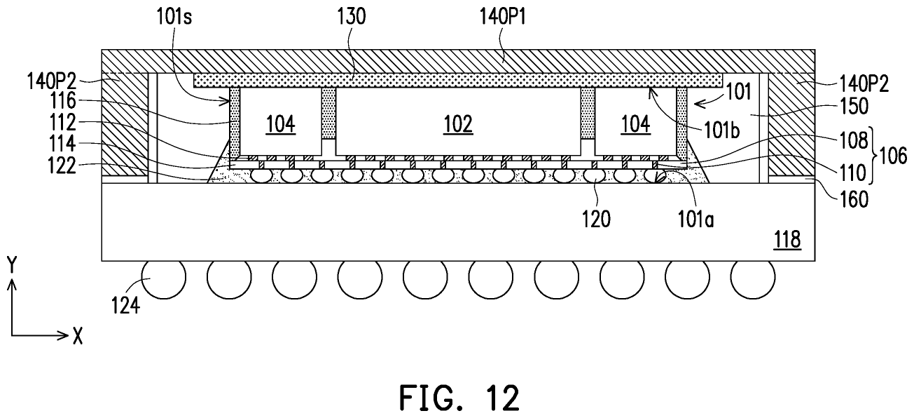

FIG. 12 to FIG. 17 illustrate the cross-sectional views of a package structure in accordance with various embodiments in accordance with some embodiments.

Referring to FIG. 12, unless further description as follows, the definition of the reference symbols and labeled representations are the same as FIG. 11, and will not be repeated herein.

In some embodiments, the TIM 130 is revealed from the insulating encapsulant 150. In some embodiments, a top surface of the TIM 130 may be substantially coplanar with a top surface of the insulating encapsulant 150. In some embodiments, an adhesive 160 is disposed on the package substrate 118, and the lid 140 is disposed on the adhesive 160, the TIM 130 and the insulating encapsulant 150. In some embodiments, the adhesive 160 is applied on the package substrate 118, and the TIM 130 is applied on the electronic device 101 at a same step. The material of the adhesive 160 may be or include thermally conductive adhesive, silicone based adhesive or epoxy resin based adhesive. The material of the adhesive may be or include rubber based having curing promoting material.

After the adhesive 160, the lid 140 is mounted onto the package substrate 118 to cover the electronic device 101. The lid 140 includes a horizontal portion 140P1 extending along the TIM 130 and a vertical portion 140P2 extending from the horizontal portion 140P1 to the package substrate 118. In some embodiments, a lateral dimension of the horizontal portion 140P1 of the lid 140 is greater than a lateral dimension of the TIM 130. The horizontal portion 140P1 of the lid 140 covers the electronic device 101 and the insulating encapsulant 150. The vertical portion 140P2 of the lid 140 is attached to the package substrate 118 through the adhesive 160. The horizontal portion 140P1 of the lid 140 is attached to the electronic device 101 through the TIM 130, and attached to package substrate 118 through the insulating encapsulant 150 and the TIM 130.

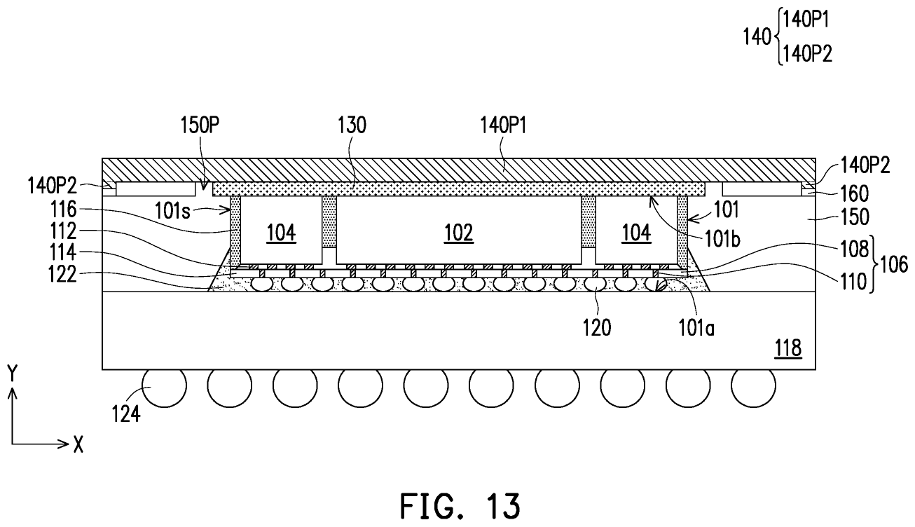

Referring to FIG. 13, unless further description as follows, the definition of the reference symbols and labeled representations are the same as FIG. 12, and will not be repeated herein.

In some embodiments, the TIM 130 is revealed from the insulating encapsulant 150. In some embodiments, a top surface of the TIM 130 may be substantially coplanar with top surfaces of the stoppers 150P of the insulating encapsulant 150. In some embodiments, an adhesive 160 is disposed on a surface of the insulating encapsulant 150 aligned with the second side 101b of the electronic device 101, and the lid 140 is disposed on the adhesive 160, the TIM 130 and the stoppers 150P of the insulating encapsulant 150. In some embodiments, the adhesive 160 is applied on the insulating encapsulant 150, and the TIM 130 is applied on the insulating encapsulant 150 and between the stoppers 150P of the insulating encapsulant 150 at a same step.

The horizontal portion 140P1 covers the electronic device 101 and the insulating encapsulant 150. The vertical portion 140P2 is attached to the insulating encapsulant 150 through the adhesive 160. The horizontal portion 140P1 of the lid 140 is attached to the electronic device 101 through the TIM 130, and attached to package substrate 118 through the stoppers 150P of the insulating encapsulant 150 and the TIM 130.

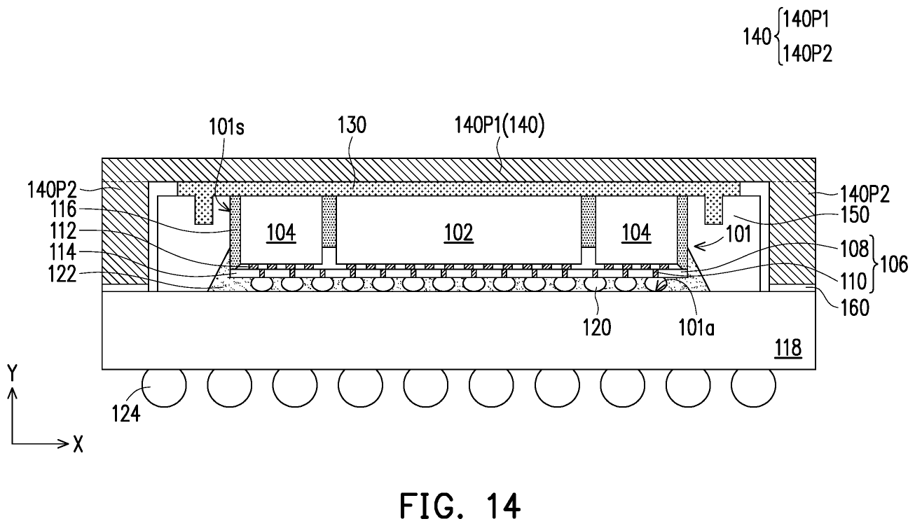

Referring to FIG. 14, unless further description as follows, the definition of the reference symbols and labeled representations are the same as FIG. 12, and will not be repeated herein.

In some embodiments, the shape of the insulating encapsulant 150 may be the same as the insulating encapsulant 150 of FIG. 8, the shape of the TIM 130 may be the same as the TIM 130 of FIG. 9. In some embodiments, the horizontal portion 140P1 of the lid 140 may be separated from the insulating encapsulant 150 through the TIM 130. In some embodiments, the lid 140 may be indirectly in contact with the insulating encapsulant 150. The protrusion 130P2b of the TIM 130 may be encapsulated by the insulating encapsulant 150.

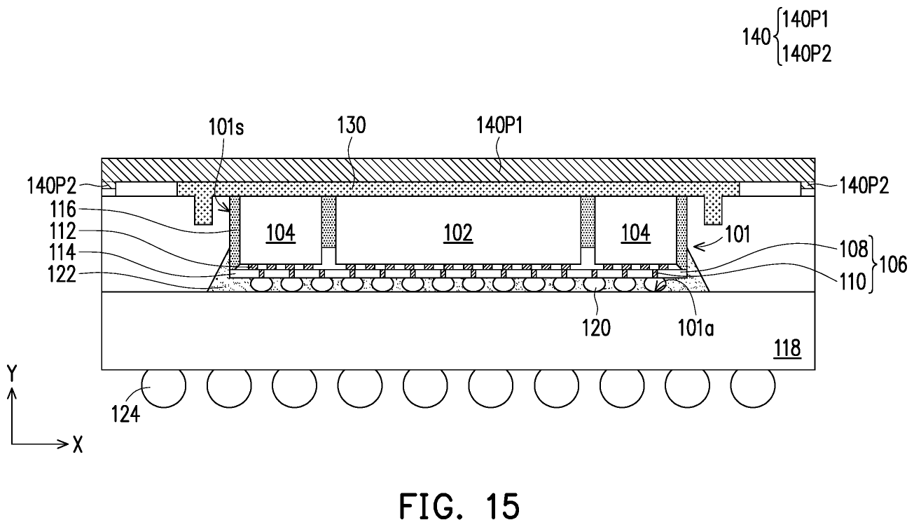

Referring to FIG. 15, unless further description as follows, the definition of the reference symbols and labeled representations are the same as FIG. 14, and will not be repeated herein.

In some embodiments, the vertical portion 140P2 of the lid 140 is attached to the insulating encapsulant 150 through the adhesive 160.

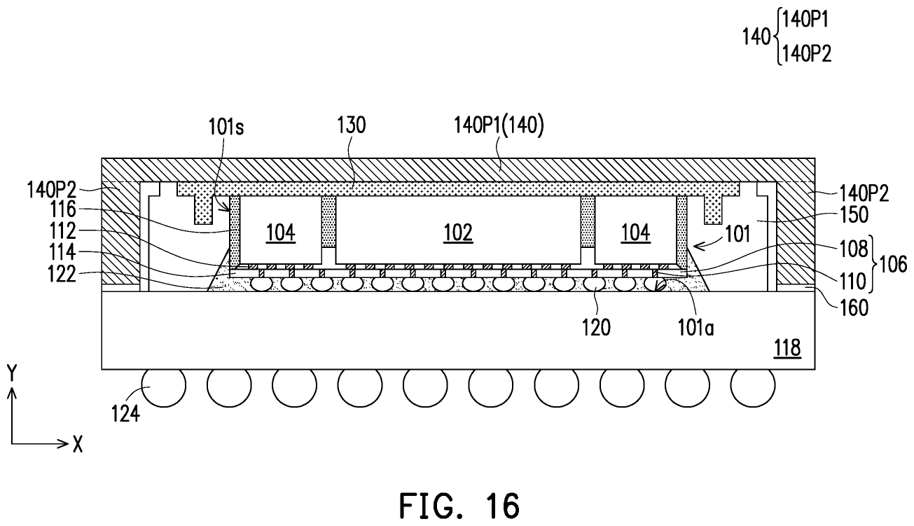

Referring to FIG. 16, unless further description as follows, the definition of the reference symbols and labeled representations are the same as FIG. 14, and will not be repeated herein.

In some embodiments, the shape of the insulating encapsulant 150 may be the same as the insulating encapsulant 150 of FIG. 6, the shape of the TIM 130 may be the same as the TIM 130 of FIG. 7. In some embodiments, a top surface of the TIM 130 may be substantially coplanar with top surfaces of the stoppers 150P of the insulating encapsulant 150.

The horizontal portion 140P1 covers the electronic device 101, the TIM 130 and the insulating encapsulant 150. The horizontal portion 140P1 of the lid 140 is attached to the electronic device 101 through the TIM 130, and attached to package substrate 118 through the stoppers 150P of the insulating encapsulant 150 and the TIM 130.

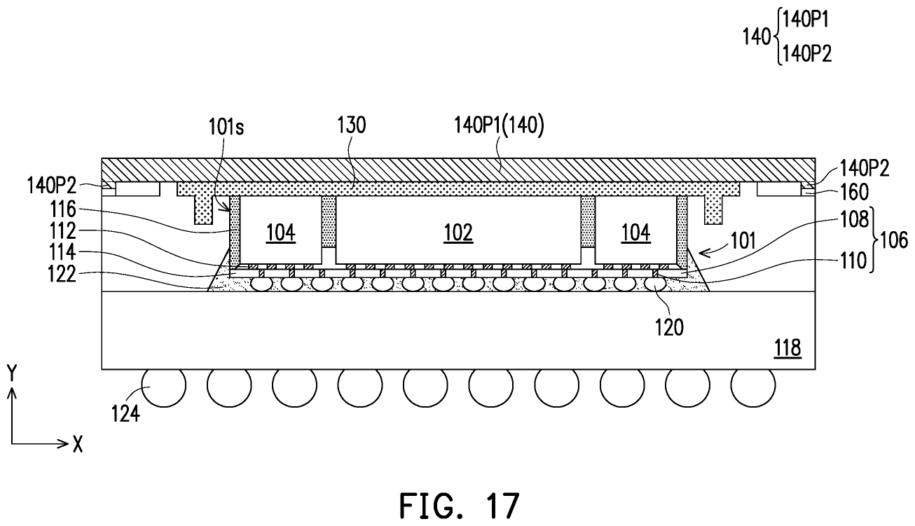

Referring to FIG. 17, unless further description as follows, the definition of the reference symbols and labeled representations are the same as FIG. 16, and will not be repeated herein.

In some embodiments, the vertical portion 140P2 of the lid 140 is attached to the insulating encapsulant 150 through the adhesive 160.

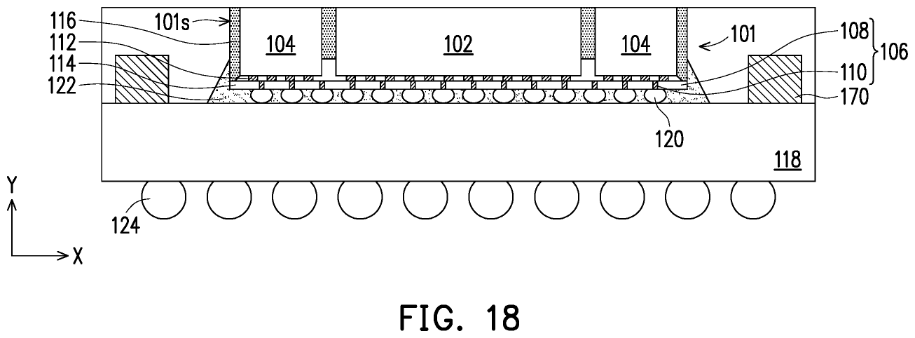

FIG. 18 to FIG. 23 illustrate the cross-sectional views of a package structure in accordance with various embodiments in accordance with some embodiments.

Referring to FIG. 18, unless further description as follows, the definition of the reference symbols and labeled representations are the same as FIG. 1, and will not be repeated herein.

In some embodiments, a fastening ring structure 170 is laterally separated from the electronic device 101 and disposed on the package substrate 118. In some embodiments, at least two portions of the fastening ring structure 170 are at opposite sides of the electronic device 101 (shown in FIG. 18). In some embodiments, the electronic device 101 is laterally surrounded by the fastening ring structure 170, viewing from a top view (not shown herein). In some embodiments, the fastening ring structure 170 is embedded in the insulating encapsulant 150. In some embodiments, the fastening ring structure 170 is encapsulated by the insulating encapsulant 150. In some embodiments, a vertical dimension of the fastening ring structure 170 is less than a thickness of the insulating encapsulant 150. In some embodiments, a top surface of the insulating encapsulant 150 may be substantially coplanar with the second side 101b of the electronic device 101.

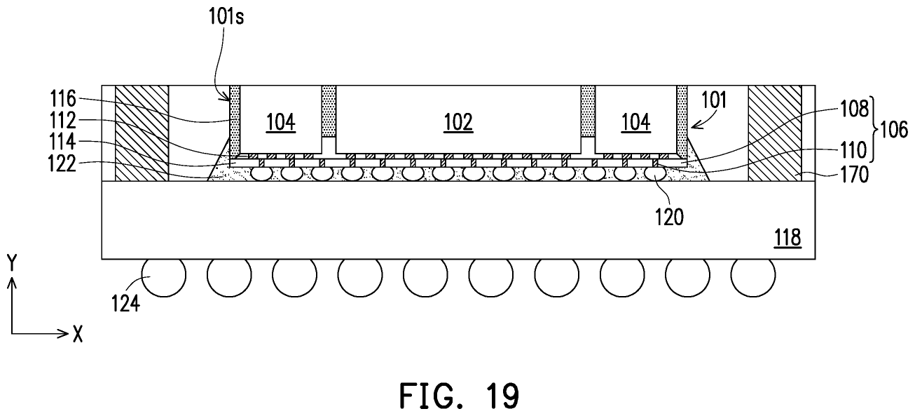

Referring to FIG. 19, unless further description as follows, the definition of the reference symbols and labeled representations are the same as FIG. 18, and will not be repeated herein.

In some embodiments, the fastening ring structure 170 is revealed from the insulating encapsulant 150. In some embodiments, a vertical dimension of the fastening ring structure 170 substantially equals to a thickness of the insulating encapsulant 150.

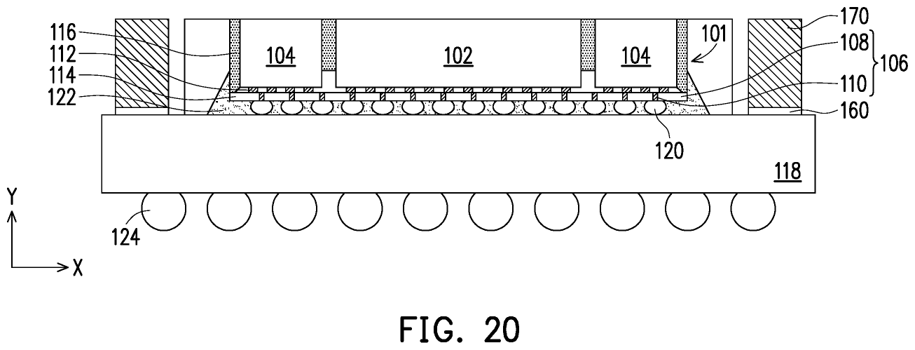

Referring to FIG. 20, unless further description as follows, the definition of the reference symbols and labeled representations are the same as FIG. 18, and will not be repeated herein.

In some embodiments, the fastening ring structure 170 is attached to the package substrate 118 through the adhesive 160 as described in FIG. 12. In some embodiments, the fastening ring structure 170 is laterally separated from the electronic device 101 and the insulating encapsulant 150. In some embodiments, the electronic device 101 and the insulating encapsulant 150 are surrounded by the fastening ring structure 170, viewing from a top view (not shown herein).

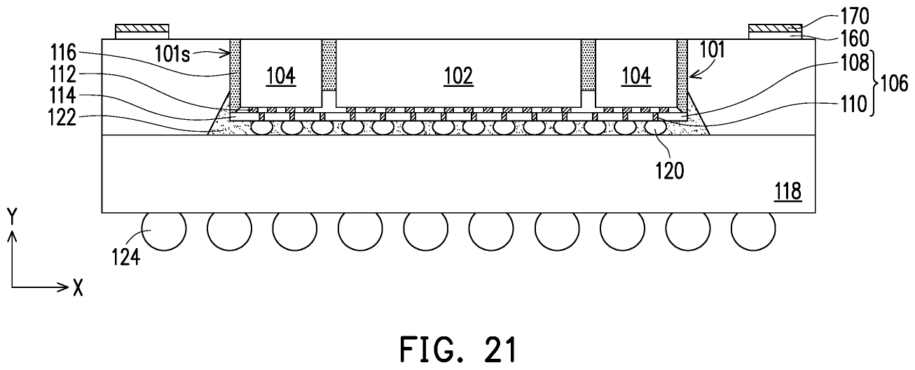

Referring to FIG. 21, unless further description as follows, the definition of the reference symbols and labeled representations are the same as FIG. 20, and will not be repeated herein.

In some embodiments, the fastening ring structure 170 is attached to the insulating encapsulant 150 through the adhesive 160 as described in FIG. 12. In some embodiments, the fastening ring structure 170 is disposed on the insulating encapsulant 150. In some embodiments, the fastening ring structure 170 is laterally separated from the electronic device 101. In some embodiments, the electronic device 101 are surrounded by the fastening ring structure 170, viewing from a top view (not shown herein).

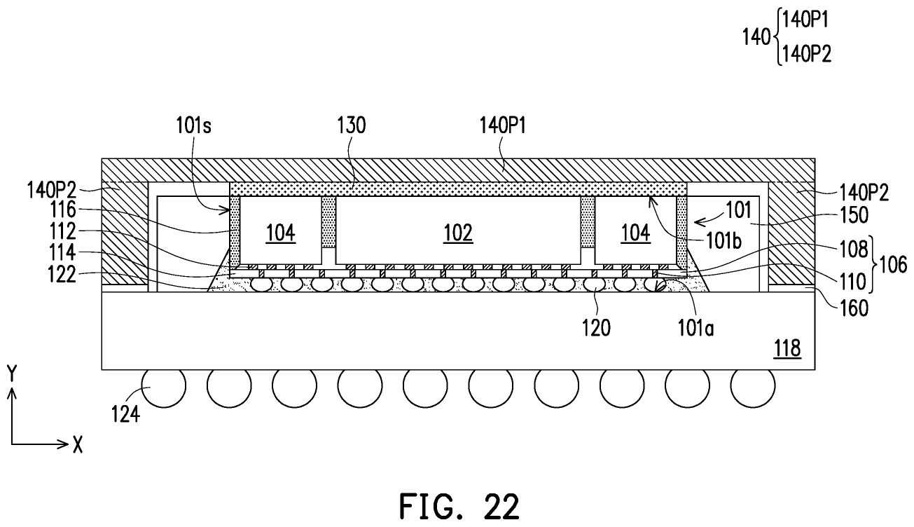

Referring to FIG. 22, unless further description as follows, the definition of the reference symbols and labeled representations are the same as FIG. 20, and will not be repeated herein.

In some embodiments, the lid 140 is attached to package substrate 118 through the adhesive 160 as described in FIG. 12. The TIM 130 is disposed on the second side 101b of the electronic device 101. The lid 140 is disposed on the TIM 130. In some embodiments, the vertical portion 140P2 of the lid 140 is attached to the package substrate 118 through the adhesive 160. In some embodiments, at least two portion of the vertical portion 140P2 of the lid 140 are at opposite sides of the electronic device 101 (shown in FIG. 22). The horizontal portion 140P1 of the lid 140 is attached to the electronic device 101 through the TIM 130. In some embodiments, horizontal portion 140P1 of the lid 140 extends along the TIM 130. In some embodiments, the horizontal portion 140P1 of the lid 140 may be separated from the electronic device 101 through the TIM 130. In some embodiments, the TIM 130 is sandwiched between the horizontal portion 140P1 of the lid 140 and the electronic device 101. In some embodiments, sidewalls of the TIM 130 may be aligned with sidewalls 101s of the electronic device 101. In some embodiments, the vertical portion 140P2 may be a fastening ring structure laterally surrounding the electronic device 101 from a top view.

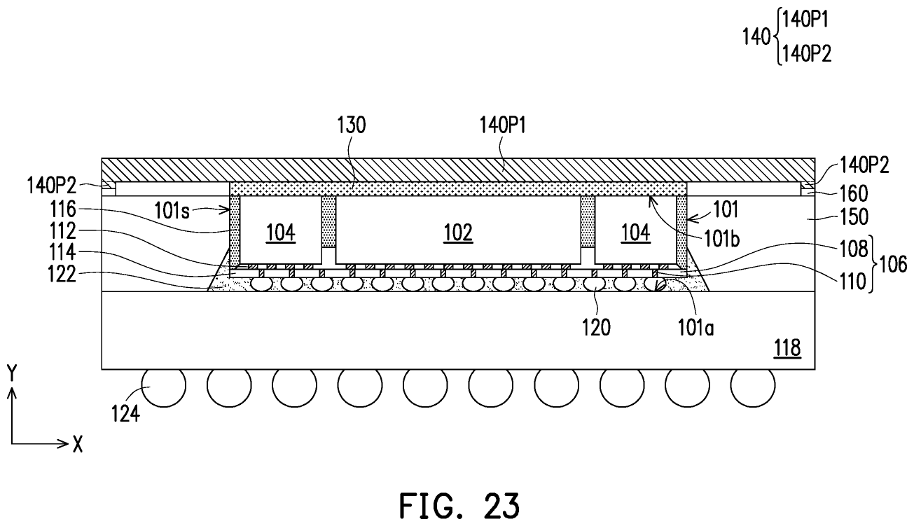

Referring to FIG. 23, unless further description as follows, the definition of the reference symbols and labeled representations are the same as FIG. 22, and will not be repeated herein.

In some embodiments, the adhesive 160 is disposed on the surface of the insulating encapsulant 150 aligned with the second side 101b of the electronic device 101. In some embodiments, the lid 140 is disposed on the adhesive 160 and the TIM 130. The vertical portion 140P2 of the lid 140 is attached to the insulating encapsulant 150 through the adhesive 160.

A package structure is provided. The package structure comprises a package substrate, an electronic device, a thermal interface material (TIM), a lid and an insulating encapsulant. The electronic device is disposed on and electrically connected to the package substrate. The TIM is disposed on the electronic device. The lid is disposed on the TIM. The insulating encapsulant is disposed on the package substrate and laterally encapsulates the electronic device and the TIM. A lateral dimension of the TIM is greater than a lateral dimension of the electronic device. The package structure is proposed to prevent a liquid metal TIM leakage to overcome TIM coverage issue when package structure warpage changes. Therefore, a reliability and a dissipating thermal performance of the package structure are improved.

In accordance with some embodiments of the present disclosure, a package structure is provided. The package structure comprises a package substrate, an electronic device, a thermal interface material (TIM), a lid and an insulating encapsulant. The electronic device is disposed on and electrically connected to the package substrate. The TIM is disposed on the electronic device. The lid is disposed on the TIM. The insulating encapsulant is disposed on the package substrate and laterally encapsulates the electronic device and the TIM. A lateral dimension of the TIM is greater than a lateral dimension of the electronic device.

In accordance with some embodiments of the present disclosure, a package structure is provided. The package structure comprises an electronic device, a package substrate, a thermal interface material (TIM), an insulating encapsulant, and a lid. The electronic device has a first side and a second side. The second side is opposite to the first side. The package substrate is disposed on the first side of the electronic device. The TIM is disposed on the second side of the electronic device. The insulating encapsulant wraps around the electronic device and the TIM. The lid is disposed on the TIM and the electronic device. The TIM comprises a main portion sandwiched between the lid and the electronic device, and a protruding portion extending from the main portion to cover sidewalls of the electronic device.

In accordance with some embodiments of the present disclosure, a package structure is provided. The package structure comprises an electronic device, a package substrate, an insulating encapsulant, and a fastening ring structure. The electronic device comprises semiconductor dies and a gap filling layer laterally encapsulating the semiconductor dies. The package substrate is disposed on a first side of the electronic device and electrically connected to the electronic device. The insulating encapsulant wraps around sidewalls of the electronic device. The fastening ring structure is disposed on the package substrate. The fastening ring structure laterally surrounds the electronic device from a top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
an electronic device disposed on and electrically connected to the package substrate;
a thermal interface material (TIM) disposed on the electronic device;
a lid disposed on the TIM; and
an insulating encapsulant disposed on the package substrate and laterally encapsulating the electronic device and the TIM, wherein a lateral dimension of the TIM is greater than a lateral dimension of the electronic device.

2. The package structure of claim 1, wherein sidewalls of the package substrate substantially align with sidewalls of the insulating encapsulant.

3. The package structure of claim 1, wherein the electronic device comprises:
an interposer substrate;
semiconductor dies disposed on and electrically connected to the interposer substrate; and
a gap filling layer disposed on the interposer substrate and laterally encapsulating the semiconductor dies.

4. The package structure of claim 3, wherein sidewalls of the interposer substrate substantially align with sidewalls of the gap filling layer.

5. The package structure of claim 3, wherein sidewalls of the gap filling layer are partially covered by the TIM.

6. The package structure of claim 1, wherein a lateral dimension of the TIM substantially equals to a lateral dimension of the lid.

7. The package structure of claim 1, wherein a lateral dimension of the lid is greater than a lateral dimension of the TIM.

8. The package structure of claim 1, wherein sidewalls of the TIM are covered by the lid.

9. The package structure of claim 1, wherein sidewalls of the TIM are covered by the insulating encapsulant.

10. A package structure, comprising:
an electronic device having a first side and a second side, wherein the second side is opposite to the first side;
a package substrate disposed on the first side of the electronic device;
a thermal interface material (TIM) disposed on the second side of the electronic device;
an insulating encapsulant wrapping around the electronic device and the TIM; and
a lid disposed on the TIM and the electronic device, wherein the TIM comprises a main portion sandwiched between the lid and the electronic device, and a protruding portion extending from the main portion to cover sidewalls of the electronic device.

11. The package structure of claim 10, wherein sidewalls of the protruding portion of the TIM are covered by the lid.

12. The package structure of claim 10, wherein sidewalls of the protruding portion of the TIM are covered by the insulating encapsulant.

13. The package structure of claim 10, wherein a lateral dimension of the TIM substantially equals to a lateral dimension of the lid.

14. The package structure of claim 10, wherein a lateral dimension of the lid is greater than a lateral dimension of the TIM.

15. The package structure of claim 10, wherein the lid comprises an upper portion and a lower portion extending between the TIM and the upper portion, and a lateral dimension of the upper portion of the lid is less than a lateral dimension of the lower portion of the lid.

16. A package structure, comprising:
an electronic device, comprising semiconductor dies and a gap filling layer laterally encapsulating the semiconductor dies;
a package substrate disposed on a first side of the electronic device and electrically connected to the electronic device;
an insulating encapsulant wrapping around sidewalls of the electronic device; and
a fastening ring structure disposed on the package substrate, wherein the fastening ring structure laterally surrounds the electronic device from a top view.

17. The package structure of claim 16, wherein the fastening ring structure is encapsulated by the insulating encapsulant.

18. The package structure of claim 16, wherein the fastening ring structure is disposed on the insulating encapsulant.

19. The package structure of claim 16, further comprising a thermal interface material (TIM) disposed on a second side of the electronic device, wherein the second side of the electronic device is opposite to the first side of the electronic device.

20. The package structure of claim 19, wherein the fastening ring structure is a lid disposed on the TIM, and wherein the lid comprises a horizontal portion extending along the TIM, and a vertical portion extending from the horizontal portion to the package substrate.
